(19) United States
(12) Patent Application Publication
(10) Pub. No.: US 2005/0106784 A1
(43) Pub. Date: May 19, 2005

(54) Method and apparatus for forming a flip chip semiconductor package and method for producing a substrate for the flip chip semiconductor package

(76) Inventor: Dingwei Xia, Singapore (SG)

Correspondence Address: George D Liu;Lawrence Y D Ho & Associates, 2101 Crystal Plaza Arc, PMB 400, Arlington, VA, 22202, US

(21) Appl. No.: 10/494,423

(22) PCT Filed: Oct. 15, 2002
(86) PCT No.: PCT/SG02/00257

(30) Foreign Application Priority Data
Nov. 7, 2001 (SG) 200106855-0

(51) Int. Cl. H01L 21/48; B29C 31/00

(52) U.S. Cl. 438/125; 438/126; 438/127; 264/272.11; 264/272.17

(57) ABSTRACT

Specifications of a flip chip package and mold compound for a package are provided to a mold flow simulator and locations of void formation in the package during molding, identified. Subsequently, a substrate (124) for the package is designed with vias (206) at the locations of void formation. During molding, air pockets at the locations of void formation escape through the vias (206) and vents (116) in the lower cavity bar (110), as mold compound flows between the die and the substrate (124) and forces the air out. In addition, the lower cavity bar (110) has a down set central location (114), which allows air to pass from the vias (206) to the vents (116). In addition, as the diameter of a via (206) is between 20-30 microns, more area on the lower surface of the substrate (124) is available for terminals arranged in an array.

### FIELD OF THE INVENTION

The present invention relates to forming a flip chip semiconductor package and a substrate therefor, and more particularly to molding a flip chip semiconductor package with the substrate.

### BACKGROUND OF THE INVENTION

As is known, a flip chip semiconductor package is one where a bumped semiconductor die is flipped over with its pattern of pads directly connected by the bumps, after reflow, to a corresponding pattern of terminals on a substrate. The assembly of die, bumps or interconnects and substrate is then molded on the substrate to encapsulate the die and bumps in mold compound. The molded package protects the die and the bumps, and allows the package to be conveniently handled. In addition, the molded package must withstand a range of operating conditions including operating at elevated temperatures.

A difficulty when molding flip chip packages is the formation of voids between the die and the substrate. Voids are pockets of air that are trapped when the mold compound flows between the die and the substrate and between the bumps, and, as is known to one skilled in the art, can adversely affect the reliability of a molded semiconductor package. There aren't any universally accepted criteria for measuring voids, however, based on a particular package and the requirements of the user of that package, a ratio of area covered by voids to total area between the die and substrate is sometimes specified as a criteria.

A method of molding a flip chip semiconductor package with a view to reducing the formation of voids is disclosed by Weber in U.S. Pat. No. 6,038,136, assigned to Hestia Technologies, Inc. of the USA. Weber teaches a mold having upper and lower cavity bars between which a flip chip package is molded on a substrate. The substrate has a single vent hole therethrough, which is centrally located; and the lower cavity bar, on which the substrate is held, has an overflow channel that is aligned with the vent hole in the substrate. The upper cavity bar has a cavity in which the flipped semiconductor die, mounted on the substrate, is enclosed when the upper and lower cavity bars come together. During molding, mold compound is injected into the cavity, and the mold compound fills the cavity surrounding the semiconductor die, and is forced into the gap between the semiconductor die and the substrate. The mold compound then flows radially inwards from each of the edges of the semiconductor die until it reaches the vent hole. The mold compound then passes through the vent hole and into the overflow channel, filling the overflow channel and forming an overflow bead on the lower surface of the substrate. The vent hole allows air between the semiconductor die and the substrate to escape as the mold compound is forced therebetween. This is intended to prevent air pockets from becoming trapped between the semiconductor die and the substrate, and thereby reducing the formation of voids. In addition, Weber teaches the use of multiple vent holes in the substrate.

When molding a particular flip chip semiconductor package, for example one having a particular semiconductor die size and a particular number of interconnects, it has been found that voids are formed relatively consistently at particular locations as the mold compound flows between the semiconductor die and the substrate. A possible cause of such void formation may be that air pockets are trapped against the sides of interconnects as the mold compound flows around the interconnects.

Hence, a disadvantage of Weber's method is that air pockets trapped around the interconnects that are located close to the vent hole can escape through the vent hole, and air pockets that are not located close to the vent hole remain trapped between the semiconductor die and the substrate.

Another disadvantage of the Weber method is the formation of the overflow bead on the lower surface of the substrate. The overflow bead consumes precious surface area of the substrate, reducing the available area for ball or pin grid array terminals for mounting and coupling the molded semiconductor package, as required by the growing densities of package inputs and outputs.

Yet another disadvantage of Weber is the relatively large size of the vent hole with a diameter in the range of 152 to 500 micrometers or microns (1×10⁻⁶ meters). Again, the large dimension of the vent hole consumes substrate real estate that can otherwise be used for inputs and outputs on a molded semiconductor package.

A still further disadvantage of Weber is the need for a lower. cavity bar having the overflow channel therein, and the complexities and cost of fabricating and using a variety of lower cavity bars for a variety of molded semiconductor packages, as the vent holes in the substrate and the overflow channel in the lower cavity bar must be aligned.

### BRIEF SUMMARY OF THE INVENTION

The present invention seeks to provide a method and apparatus for forming a flip chip semiconductor package and method and apparatus for producing a substrate for the flip chip semiconductor package, which overcomes, or at least reduces, the abovementioned problems of the prior art.

Accordingly, in one aspect, the present invention provides at least one mold piece for molding at least one semiconductor package, the at least one mold piece comprising:

a molding surface for receiving a substrate, the substrate having at least on via therethrough, and the substrate having at least one semiconductor die flip chip mounted thereto; and

at least one vent therein which extends from the molding surface, the at least one vent for pneumatically coupling to the at least one via.

In another aspect the present invention provides a method for molding at least one flip chip semiconductor package, the method comprising the steps of;

a) providing at least one substrate having a plurality of vias therethrough, the plurality of vias being at predetermined locations;

b) flip chip mounting at least one semiconductor die to the substrate;

c) providing at least one mold piece having a molding surface for receiving the substrate, the at least one mold piece having a plurality of vents extending from the molding surface;

d) disposing the substrate with the at least one semiconductor die thereon on the molding surface;

e) enclosing the substrate in a mold cavity formed by another molding surface of at least another mold piece; and

f) injecting mold compound into the mold cavity, and thereby expressing air from between the at least one substrate and the at least one semiconductor die through at least some of the plurality of vias and at least some of the plurality of vents.

In yet another aspect the present invention provides a method for producing a substrate for forming at least one flip chip semiconductor package, the method comprising the steps of:

a) simulating molding the at least one flip chip semiconductor package to produce simulation results indicating locations of void formation within the at least one flip chip'semiconductor package;

b) selecting some of the locations of void formation; and

c) fabricating the substrate with vias at the selected locations of void formation.

### BRIEF DESCRIPTION OF THE DRAWINGS

An embodiment of the present invention will now be fully described, by way of example, with reference to the drawings of which:

FIG. 1 shows a side sectional view of a molding apparatus in accordance with the present invention;

FIG. 2 shows an enlarged view of a portion of the molding apparatus in FIG. 1;

FIG. 3 shows a plan view of the lower cavity bar I FIG. 1;

FIG. 4 shows a plan view of the upper cavity bar I FIG. 1;

FIG. 5 shows a flowchart of a molding process using the molding apparatus in FIG. 1;

FIG. 6 shows the flow of mold compound within the mold cavity of the molding apparatus in FIG. 1;

FIG. 7 shows a flowchart of a process for producing the substrate in FIG. 1; and

FIG. 8 shows results of a simulation in accordance with the flowchart in FIG. 7.

### DETAIL DESCRIPTION OF THE DRAWINGS

For a particular molded semiconductor package, the specifications of the package and the mold for forming the package are provided to a mold flow simulator that identifies the locations of void formation in the package. Subsequently, a substrate for the particular package is designed with vias at the locations of void formation. During molding, air pockets at the locations of void formation escape through the vias and vents in the lower cavity bar, as mold compound flows between the die and the substrate and forces the air out. In addition, the lower cavity bar has a down set central location coupled to the vent, hence avoiding the need to align the vias in the substrate with the vent as the down set allows air to pass from the vias to the vent wherever the vias are located within the downset area. Further, a lower cavity bar with a particular downset may be used for a variety of substrates of the same size but having different via locations. In addition, as the lower cavity bar does not have an overflow channel, as in the prior art, and the diameter of a via is between 20-30 microns, more area on the lower surface of the substrate is available for terminals arranged in an array.

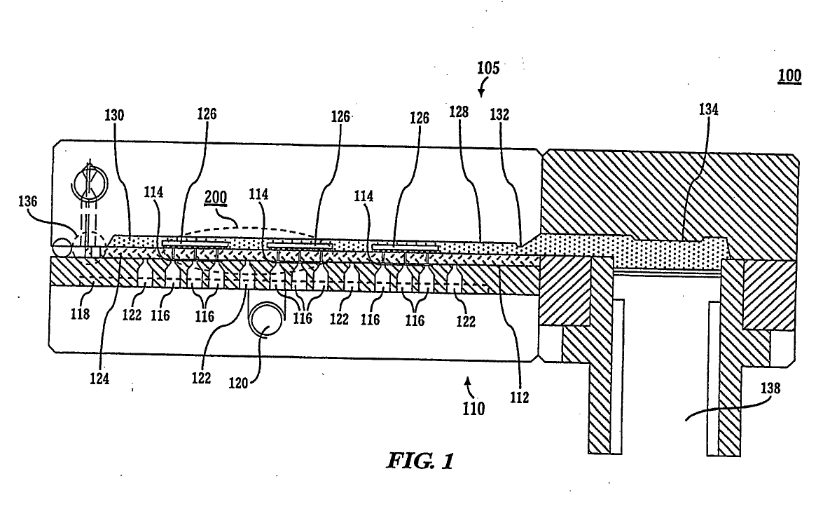

FIG. 1 shows a portion of a molding apparatus 100 comprising an upper mold piece or upper cavity bar 105 and a lower mold piece or lower cavity bar 110. As is known by one skilled in the art, the upper cavity bar 105 is mounted to an upper portion of a press (not shown), and the lower cavity bar 110 is mounted to a lower portion of a press (not shown). In a conventional molding press, the upper portion is not movable and the lower portion moves in a vertical direction between an upper molding position and a lower open position. Consequently, the lower mold piece 110 is moved vertically between a lower open position and a raised molding position. The raise molding position is shown.

The lower cavity bar 110 has an upper surface 112, with downset portions 114, one for each of the semiconductor packages being formed. The downset portions are 15-20 microns recessed in the upper surface 112 of the lower cavity bar 110. Each of the downset portions 114 has a number of vents 116 that extend from the downset portions 114 through the lower cavity bar 110, to a channel 118. The channel 118 is, in turn, coupled to an outlet 120. In addition, vacuum inlets 122 in the upper surface of the lower cavity bar 110 are coupled to a vacuum source (not shown) to secure a substrate 124 on the lower cavity bar 110. It will be appreciated that here the vents 116 and the vacuum inlets 122 are coupled to the channel 118. Consequently, a vacuum is applied to the vacuum inlets and the vents 116. In an alternative embodiment of the present invention, only the vacuum inlets 122 may be coupled to apply a vacuum, while the vents 116 are not coupled to apply a vacuum. The vents may be left open to ambient air pressure or coupled to an alternative vacuum source to apply a different vacuum force than that applied at the vacuum inlets 122. On the substrate 124 are three semiconductor dies 126 that are flip-chip mounted thereto. A more detailed description of the flip chip mounting will be provided later. The package that is being molded here is similar to what is referred to as a quad-flat-non-leaded (QFN), where a number of semiconductor dies are encapsulated in a single molding, and subsequently singulated to produce individual semiconductor packages.

The upper cavity bar 105 has a lower surface 128 that forms a molding cavity 130 with the substrate 124, when the upper and lower cavity bars 105 and 110 are in the molding position. The lower surface 128 also includes a gate 132, which lies between a cull 134 and the cavity 130. In the molding position, the three semiconductor dies 126 are enclosed in the cavity 130. A plunger 138 moves in a vertical direction to force mold compound in the cull 134 into the cavity 130. A location 136 opposite the gate 132, includes a vent at the end of the cavity 130 as is known in the art, and no further details are provided herein.

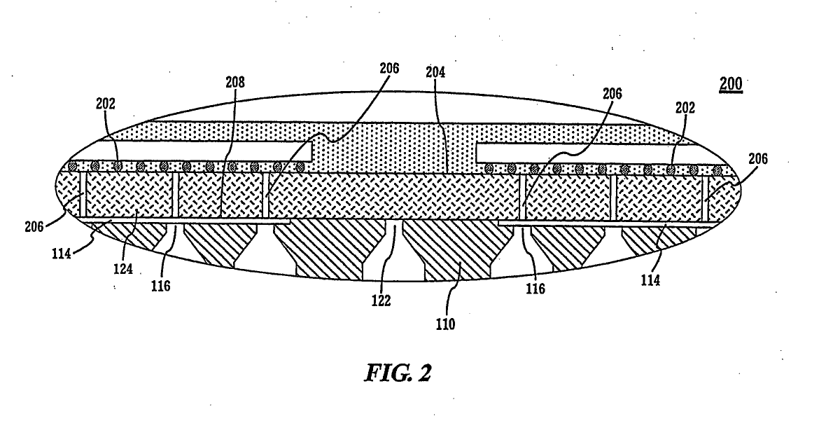

FIG. 2 shows an enlarged view of a portion 200 of the upper and lower cavity bars 105 and 110. Interconnects 202 mount the semiconductor dies 126, and electrically couple the pads (not shown) on the flipped dies 126 to terminals (not shown) on the upper surface 204 of the substrate 130. The interconnects 202 are sometimes referred to as bumps, and are typically formed on the pads of the semiconductor dies 126. The dies 126 are then flipped over and the bumps 126 aligned with the terminals before the dies are placed on the substrate 124. A subsequent reflow process causes the bumps 202, typically made of solder, to melt and couple the pads to the terminals. The bumps may be made of a variety of materials, and a layer of solder is usually incorporated into the structure of the bump.

As mentioned above, the vents 116 are coupled to the downset portions 114, and the substrate 124 has vias 206 that extend from the upper surface 204 of the substrate to the lower surface 208, which is within the downset portions 114. The vias 206 are located between the interconnects 202 at predetermined locations, hence when vacuum is applied at the predetermined locations through the vias, the vacuum advantageously removes pockets of air and reduces the formation of voids at the predetermined locations.

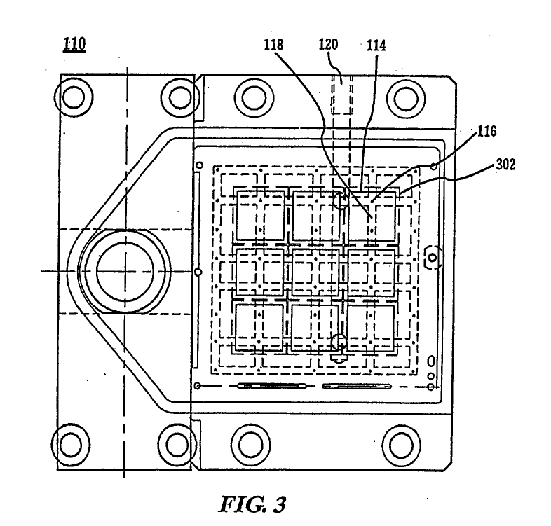

FIG. 3 shows the lower cavity bar 110 indicating the downset portions 114 with outlines 302 of the semiconductor dies 126 overlaid. The downset portions 114 are made smaller than the outlines 302 of the semiconductor dies 126 to ensure sufficient support for the portion of the substrate 124 below the semiconductor dies 126.

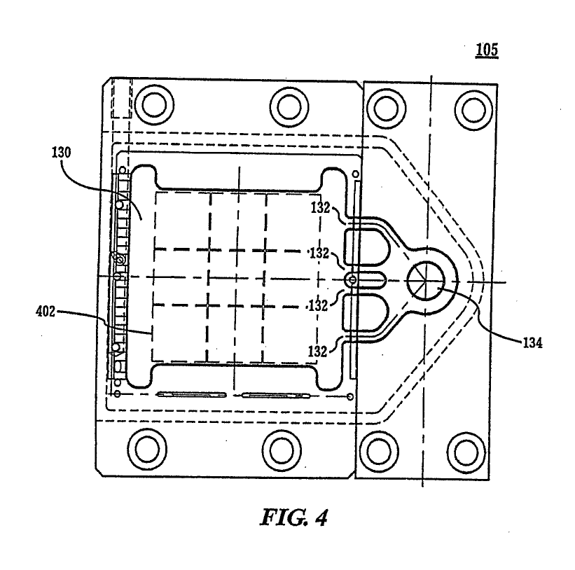

FIG. 4 show the upper cavity bar 105 with outlines 402 of the semiconductor dies 126 overlaid, indicating the position of the semiconductor dies 126 within the cavity 130.

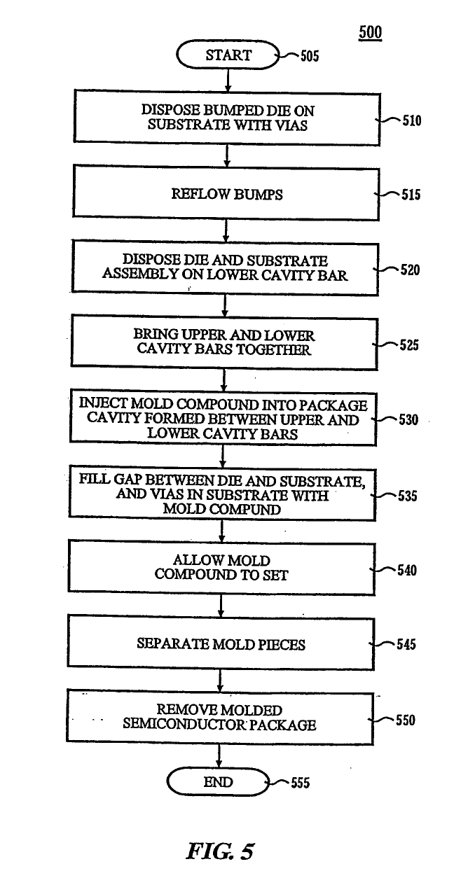

With additional reference now to FIG. 5, a process 500 for molding a semiconductor package in accordance with the present invention, starts 505 with disposing 510 bumped semiconductor dies 126 on the substrate 124 having the corresponding pattern of pads thereon and the vias 206 at the predetermined locations. The semiconductor dies 126 and the substrate 124 are then reflowed 515 in a reflow chamber causing the bumps to form the interconnects 202. The assembly of the substrate 124 and the semiconductor dies 126 is then disposed 520 on the upper surface 112 of the lower cavity bar 110. Both the upper and lower cavity bars 105 and 110 are preheated and maintained at an elevated molding temperature. There will of course be the necessary alignment features such as locating pins on the upper surface 112, and corresponding apertures in the substrate 124 to ensure proper location of the substrate 124.

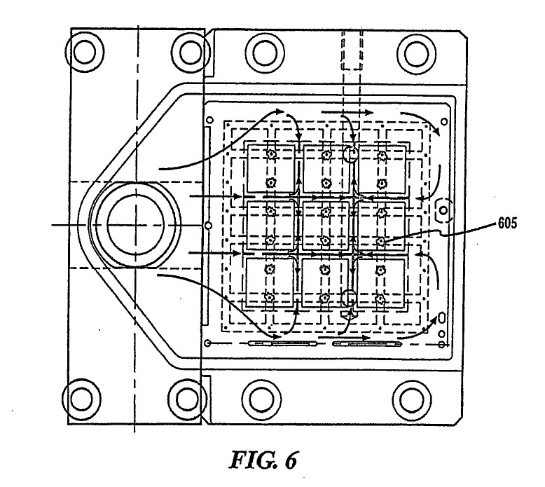

Next, the upper and lower cavity bars 105 and 110 are brought 525 together, enclosing the semiconductor dies 126 in the molding cavity 130 formed by the molding surface 128 of the upper cavity bar 105, and the substrate 124. With a deposit of mold compound in the cull 134, the plunger 138 moves upwards compressing the mold compound, and under the imposed heat and pressure, the mold compound changes to a molten liquefied state. The molten compound is injected 530 from the cull 134 through the gate 132 and into the cavity 130. With reference to FIG. 6, the arrows show the flow of the mold compound within the cavity 130. The flow of the mold compound exhibits what is sometimes called a wrapping effect. This is where the mold compound flows around the semiconductor dies 126 and then, after surrounding the semiconductor dies 126, begins flowing inwardly between the semiconductor dies 126 and the substrate 124, thus filling 535 the gap between the semiconductor dies 126 and the substrate 124.

Air in air pockets 605 trapped between the semiconductor dies 126 and the substrate 124 are gradually forced out through the vias 202 by the flow of mold compound, through the downset portions 114 and the vents 116. Where a vacuum is employed, the flow of the mold compound and the displacement of the air in the air pockets 605 is further enhanced. Thus, advantageously facilitating the flow of the mold compound between the semiconductor dies i26 and the substrate 124, and reducing the formation of voids. The mold compound continues to flow between the semiconductor dies 126 and the substrate 124 and then into the vias 116. The mold compound can flow through the vias 116 and form dimples at the opening of the vias on the lower surface of the substrate 124.

The mold compound is then allowed 540 some time to set, as determined by a variety of parameters including the type of mold compound that is used. The upper and lower cavity bars 105 and 110 are subsequently separated 545 and the molded semiconductor packages, now being a part of a single molding, is removed 550 from the lower cavity bar 110, and the molding process 500 ends 555. As is known a singulation process follows to produce the individual semiconductor packages.

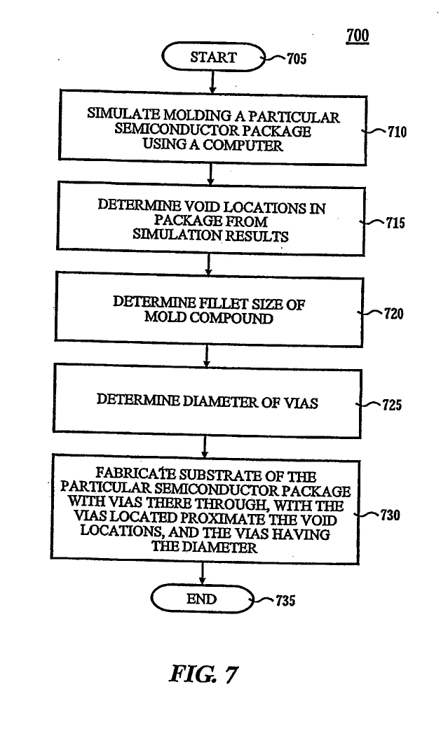

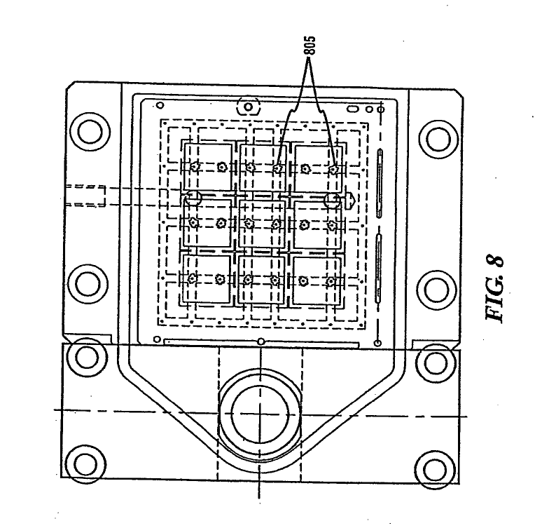

With reference to FIG. 7 a process 700 for fabricating a substrate with the vias at the predetermined locations starts 705 with simulating 710 molding the particular semiconductor package using a computer program to determine the mold flow pattern when molding that package using the upper and lower cavity bars 105 and 110, and a particular mold compound. Examples of such simulation software applications are C-MOLD by Exicad Corporation of the USA, and MOLD-FLOW of Australia From the simulation results, the next step is to determine 715 the locations of voids in the package, and determine 720 the fillet size of the particular mold compound, for example 10-20 microns. It will be appreciated by one skilled in the art that voids are discernible from the simulation results, as the primary purpose of such simulation programs is determining the location of voids. The fillet size of the mold compound on the other hand is a part of the specification of the mold compound, and is readily determined from the manufacturer. FIG. 8 shows the results of a simulation indicating the locations of voids 805. There is a tendency for the voids to occur in central locations between the semiconductor dies 126 and the substrate 124.

The location of the voids provide an indication of the locations, sometimes referred to as target locations, where vias are required in the substrate; while the fillet size of the mold compound will determine the size of the vias e.g. the diameter. With this information, the substrate is then fabricated 730 using conventional processes to form the vias having the required dimensions at the target locations, and the process 700 ends 735.

Although the simulation results indicate the locations of the voids, there are compromises that need to be made when actually selecting the location of the vias. Considerations that have to be made are, the tolerance of the simulation results, the availability of space on the substrate for the vias, the layout of runners in the substrate, the size of the voids, the number of vias required, and the costs of adding the vias to a substrate. There is also a limit to the number of vias that may be provided for each semiconductor package as vias are openings in the package that can allow moisture into the package and adversely affect the reliability of the package. Hence, the size of the die and the type of semiconductor package also affect the number and size of vias on a substrate in a semiconductor package. With a die size of 11.8 square millimeters (mm²), two to three vias are required for each die, and the vias each have a diameter of 20-30 microns.

Hence, the present invention, as described, provides a method of molding a flip chip semiconductor package that reduces the formation of voids in the semiconductor package.

This is accomplished by simulating the molding of the semiconductor package to determine the locations of void formation, and then fabricating a substrate for the semiconductor package with vias at the locations of void formation. In addition, a mold piece for molding the semiconductor package is made with vents that allow air at the locations of void formation. When the semiconductor package is formed using the substrate and the mold piece, air from the locations of void formation flows through the vias to the vents, during molding.

The present invention therefore provides a method and apparatus for forming a flip chip semiconductor package and method for producing a substrate for the flip chip semiconductor package, which overcomes, or at least reduces, the abovementioned problems of the prior art.

It will be appreciated that although only one particular embodiment of the invention has been described in detail, various modifications and improvements can be made by a person skilled in the art without departing from the scope of the present invention.

1. At least one mold piece for molding at least one semiconductor package, the at least one mold piece comprising:
a molding surface for receiving a substrate, the substrate having at least one via therethrough, and the substrate having at least one semiconductor die flip chip mounted thereto; and
at least one vent therein which extends from the molding surface, the at least one vent for pneumatically coupling to the at least one via,
wherein at least a portion of the molding surface is downset, and wherein the at least one vent is located within the downset portion.

2. At least one mold piece in accordance with claim 1, wherein the at least one via comprises a plurality of vias at predetermined locations of the substrate, wherein the at least one vent comprises a plurality of vents, and wherein at least some of the plurality of vias at predetermined locations of the substrate are pneumatically coupled to at least some of the plurality of vents.

3. At least one mold piece in accordance with claim 1 wherein the at least one mold piece further comprises at least one vacuum inlet that extends from the molding surface for securing the substrate to the molding surface.

4. At least one mold piece in accordance with claim 1 wherein the at least one via comprises a plurality of vias and at least some of the plurality of vias are located on the substrate to pneumatically couple to the downset portion.

5. (canceled)

6. At least one mold piece in accordance with claim 1 wherein the at least one mold piece further comprises at least one pneumatic pathway coupled to the at least one vent.

7. At least one mold piece in accordance with claim 6 wherein the at least one pneumatic pathway further comprises at least one outlet.

8. At least one mold piece in accordance with claim 6 wherein at least one outlet is adapted for coupling to a vacuum source.

9. A method for molding at least one flip chip semiconductor package, the method comprising the steps of;
a) simulating molding at least one flip chip semiconductor package to produce simulation results indicating locations of void formation within the flip chip semiconductor package;
b) selecting some of the locations of void formation;
c) fabricating a substrate with vias at the selected locations of void formation;
d) flip chip mounting at least one semiconductor die to the substrate;
e) providing at least one mold piece having a molding surface for receiving the substrate, the at least one mold piece having a plurality of vents extending from the molding surface;
f) disposing the substrate with the at least one semiconductor die thereon on the molding surface;
g) enclosing the substrate in a mold cavity formed by another molding surface of at least another mold piece; and
h) injecting mold compound into the mold cavity, and thereby expressing air from between the at least one substrate and the at least one semiconductor die through at least some of the plurality of vias and at least some of the plurality of vents.

10. (canceled)

11. A method in accordance with claim 9 wherein step (b) comprises the steps of:
b1) bumping the at least one semiconductor die;
b2) mounting the bumped at least one semiconductor die on the at least one substrate; and
b3) reflowing the assembly of the bumped at least one semiconductor die and the at least one substrate.

12. A method in accordance with claim 9 wherein step (c) comprises the steps of:
c1) providing specifications of the at least one substrate and the predetermined locations of the plurality of vias; and
c2) fabricating the at least one mold piece having the plurality of vents extending from the molding surface particular for molding the at least one substrate with the plurality of vias at the predetermined locations.

13. A method in accordance with claim 9 wherein step (d) comprises the steps of:
d1) locating the at least one substrate on the molding surface; and
d2) securing the at least one substrate to the molding surface.

14. A method in accordance with claim 9 wherein step (e) comprises the steps of:
e1) bringing the another mold piece and the at least one mold piece together; and
e2) keeping the another mold piece and the at least one mold piece together until after the mold compound has cured.

15. A method for producing a substrate for forming at least one flip chip semiconductor package, the method comprising the steps of:
a) simulating molding the at least one flip chip semiconductor package to produce simulation results indicating locations of void formation within the at least one flip chip semiconductor package;
b) selecting some of the locations of void formation; and
c) fabricating a substrate with vias at the selected locations of void formation.

16. A method in accordance with claim 15 wherein step (a) comprises the step of using a molding simulation program on a computer.

17. A method in accordance with claim 15 wherein step (b) comprises selecting the locations of void formation where relatively larger voids tend to form.

18. A method in accordance with claim 15 wherein step (b) comprises the step of selecting the locations of void formations where locating a via will not interfere with existing features of the at least one substrate.

19. A method in accordance with claim 15 wherein step (b) comprises the step of selecting the minimal number of vias to avoid adversely affecting reliability of the at least one flip chip semiconductor package.

20. A method in accordance with claim 15, prior to step (c), comprises the steps of:
determining fillet size of mold compound to be used for forming the at least one flip chip semiconductor package; and
setting the size of each of the vias to a size not substantially greater than the fillet size.
